(19) United States
(12) Patent Application Publication
(10) Pub. No.: US 2026/0076046 A1
(43) Pub. Date: Mar. 12, 2026

(54) DISPLAY DEVICE AND ELECTRONIC DEVICE INCLUDING DISPLAY DEVICE

(71) Applicant: Samsung Display Co., Ltd., Yongin-si (KR)

(72) Inventors: Kon Haeng LEE, Yongin-si (KR); Chang Woo KAHNG, Yongin-si (KR); Won Tae KIM, Yongin-si (KR); Jung Kook PARK, Yongin-si (KR); Yong Je JEON, Yongin-si (KR); Seok Hyun JUNG, Yongin-si (KR)

(21) Appl. No.: 19/197,762

(22) Filed: May 2, 2025

(30) Foreign Application Priority Data
Sep. 12, 2024 (KR) 10-2024-0125036

(51) Int. Cl. H10K 59/131; G09G 3/3233; H10K 59/124; H10K 59/35

(52) U.S. Cl. CPC H10K 59/131; G09G 3/3233; H10K 59/124; G09G 2300/0426; G09G 2300/0452; G09G 2300/0819; G09G 2300/0852; G09G 2300/0861; H10K 59/35

(57) ABSTRACT

A display device includes: a substrate; an anode electrode on the substrate; and a first voltage line between the substrate and the anode electrode and configured to receive a negative voltage, wherein in the first voltage line, a first portion overlapping the anode electrode has a width greater than a second portion not overlapping the anode electrode.

### CROSS-REFERENCE TO RELATED APPLICATION

The present application claims priority to and the benefit of Korean Patent Application No. 10-2024-0125036, filed on Sep. 12, 2024, in the Korean Intellectual Property Office, the entire disclosure of which is incorporated herein by reference.

### BACKGROUND

### 1. Field

Aspects of some embodiments of the present disclosure relate to a display device and an electronic device including the display device.

### 2. Description of the Related Art

In recent years, as interest in information displays has increased, research and development on display devices have been continuously conducted.

The above information disclosed in this Background section is only for enhancement of understanding of the background and therefore the information discussed in this Background section does not necessarily constitute prior art.

### SUMMARY

Aspects of some embodiments of the present disclosure include a display device with relatively improved screen quality and enhanced reliability.

Aspects of some embodiments of the present disclosure include an electronic device including the display device.

Aspects of embodiments according to the present disclosure are not limited to the above-described characteristics, and other technical characteristics not mentioned will be more clearly understood by those skilled in the art from the following description.

According to some embodiments of the present disclosure, a display device includes: a substrate; an anode electrode on the substrate; and a first voltage line between the substrate and the anode electrode and receiving a negative voltage. In the first voltage line, a first portion overlapping the anode electrode may have a width greater than a second portion not overlapping the anode electrode.

According to some embodiments, the display device may further include an insulating layer between the anode electrode and the first voltage line. An upper surface of the insulating layer may be in contact with the anode electrode, and a lower surface of the insulating layer may be in contact with the first voltage line.

According to some embodiments, the anode electrode and the first voltage line may constitute a capacitor.

According to some embodiments, the first voltage line may receive an anode initialization voltage.

According to some embodiments, the first voltage line may receive a gate initialization voltage.

According to some embodiments, the display device may further include a first transistor connected between a first power source voltage line and the anode electrode and having a gate electrode connected to a first node; a second transistor connected between the first node and a first initialization voltage line and having a gate electrode connected to a first gate line; a third transistor connected between the anode electrode and a second initialization voltage line and having a gate electrode connected to a second gate line; and a light emitting element connected between the anode electrode and a second power source voltage line.

According to some embodiments, the second initialization voltage line may be the first voltage line.

According to some embodiments, the first initialization voltage line may be the first voltage line.

According to some embodiments, the first voltage line may include titanium and aluminum.

According to some embodiments, the display device may further include a second voltage line on the substrate and receiving a positive voltage.

According to some embodiments, the second voltage line may receive a data voltage.

According to some embodiments, the second voltage line may receive a power source voltage.

According to some embodiments of the present disclosure, a display device includes: a substrate; first to third light emitting elements on the substrate and respectively including first to third anode electrodes respectively in first to third sub-pixel areas; and a first voltage line between the substrate and the first to third anode electrodes and receiving a negative voltage. In the first voltage line, at least one first portion may have a width greater than a second portion other than the first portion, and the first portion may overlap at least one of the first to third anode electrodes.

According to some embodiments, the first to third light emitting elements may emit light of different colors.

According to some embodiments, the first light emitting element may emit red light, the second light emitting element may emit green light, and the third light emitting element may emit blue light.

According to some embodiments, the first portion may overlap one of the first to third anode electrodes.

According to some embodiments, the first portion may overlap each of two or more of the first to third anode electrodes.

An electronic device includes a processor to provide input image data; and a display device to display an image based on the input image data. The display device includes a substrate; an anode electrode on the substrate; and a first voltage line between the substrate and the anode electrode and receiving a negative voltage, wherein in the first voltage line, a first portion overlapping the anode electrode has a width greater than a second portion not overlapping the anode electrode.

Specific details of other embodiments are included in the detailed description and drawings.

### BRIEF DESCRIPTION OF THE DRAWINGS

The accompanying drawings, which are included to provide a further understanding of the inventive concepts, and are incorporated in and constitute a part of this specification, illustrate exemplary embodiments of the inventive concepts, and, together with the description, serve to explain principles of the inventive concepts.

FIG. 1 is a block diagram illustrating aspects of a display device.

FIG. 2 is a block diagram illustrating aspects of one of sub-pixels of FIG. 1.

FIG. 3 is a circuit diagram illustrating aspects of a sub-pixel of FIG. 2.

FIG. 4 is a circuit diagram illustrating aspects of the sub-pixel of FIG. 2.

FIG. 5 is a plan view illustrating aspects of a display panel of FIG. 1.

FIG. 6 is a cross-sectional view illustrating aspects of the display panel of FIG. 5.

FIG. 7 is a cross-sectional view illustrating aspects of the display panel of FIG. 5.

FIG. 8 is a plan view illustrating an enlarged portion of a display area in the display panel of FIG. 5.

FIG. 9 is a cross-sectional view taken along the line I-I′ in FIG. 8.

FIG. 10 is a plan view illustrating aspects of the display panel of FIG. 8.

FIG. 11 is a block diagram of an electronic device according to some embodiments.

FIG. 12 shows schematic views of various embodiments of an electronic device.

### DETAILED DESCRIPTION

As the present invention allows for various changes and numerous embodiments, particular embodiments will be illustrated in the drawings and described in detail in the written description. However, this is not intended to limit the scope of embodiments according to the present disclosure to particular modes of practice, and it is to be appreciated that all changes, equivalents, and substitutes that do not depart from the spirit and technical scope of the present invention are encompassed in the present invention.

In describing each drawing, similar reference numerals are used for similar components. In the attached drawings, the dimensions of the structures are enlarged from the actual dimensions to clarify the present invention. It will be understood that, although the terms “first”, “second”, etc. may be used herein to describe various elements, these elements should not be limited by these terms. These terms are only used to distinguish one element from another element. For instance, a first element discussed below could be termed a second element without departing from the scope of embodiments according to the present disclosure. Similarly, the second element could also be termed the first element.

It will be further understood that the terms “comprise”, “include”, “have”, etc. used in the disclosure, specify the presence of stated features, integers, steps, operations, elements, components, and/or combinations of them but do not preclude the presence or addition of one or more other features, integers, steps, operations, elements, components, and/or combinations thereof. In addition, when a first part such as a layer, film, region, plat, etc. is on a second part, the first part may be not only “directly on” the second part but a third part may intervene between them. Furthermore, in the disclosure, when a first part such as a layer, film, region, plat, etc. is formed on a second part, a direction in which the first part is formed is not limited to an upper direction of the second part, but may include a side or a lower direction of the second part. To the contrary, when a first part such as a layer, film, region, plat, etc. is “under” a second part, the first part may be not only “directly under” the second part but a third part may intervene between them.

Hereinafter, aspects of some embodiments of the present disclosure and other matters necessary for those skilled in the art to easily understand the contents of the present disclosure will be described in more detail with reference to the attached drawings. In the description below, the singular expressions are intended to include the plural expressions as well, unless the context clearly indicates that it includes only the singular.

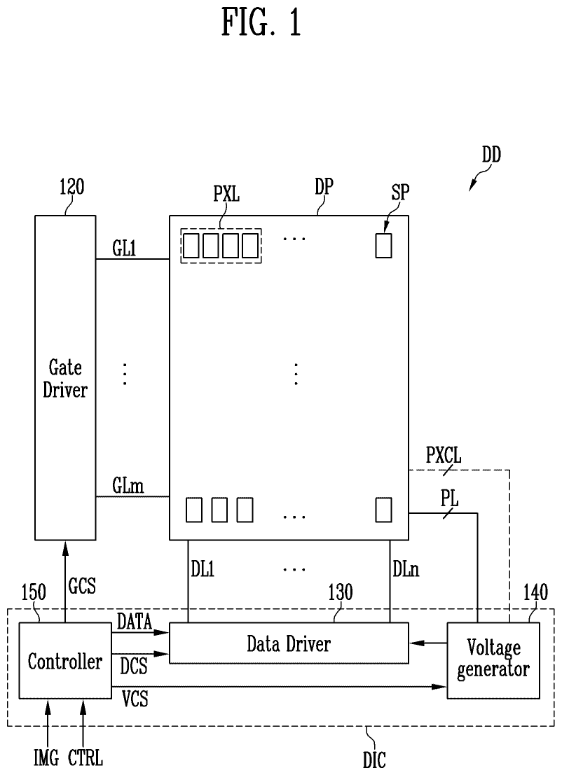

FIG. 1 is a block diagram illustrating aspects of a display device.

Referring to FIG. 1, a display device DD may include a display panel DP, a gate driver 120, a data driver 130, a voltage generator 140, and a controller 150.

The display panel DP may include sub-pixels SP. The sub-pixels SP may be connected to the gate driver 120 through first to m-th gate lines GL1 to GLm. The sub-pixels SP may be connected to the data driver 130 through first to n-th data lines DL1 to DLn.

The sub-pixels SP may generate light of two or more colors. For example, each of the sub-pixels SP may generate light of a color such as red, green, blue, cyan, magenta, yellow, or the like.

Two or more sub-pixels among the sub-pixels SP may constitute one pixel PXL. For example, the pixel PXL may include four sub-pixels as shown in FIG. 1. In this way, the pixel PXL may emit light of various colors and various luminances depending on the combination of light emitted from the sub-pixels.

The gate driver 120 may be connected to the sub-pixels SP arranged in a row direction through the first to m-th gate lines GL1 to GLm. The gate driver 120 may output gate signals to the first to m-th gate lines GL1 to GLm in response to a gate control signal GCS. According to some embodiments, the gate control signal GCS may include a start signal indicating the start of each frame, a horizontal synchronization signal, and the like.

The gate driver 120 may be located on one side of the display panel DP. However, embodiments are not limited thereto. For example, the gate driver 120 may be divided into two or more drivers that are physically and/or logically separated. Such drivers may be located on one side of the display panel DP and the other side of the display panel DP opposite to the one side. In this way, the gate driver 120 may be arranged in various forms on the periphery of the display panel DP according to some embodiments.

The data driver 130 may be connected to the sub-pixels SP arranged in a column direction through the first to n-th data lines DL1 to DLn. The data driver 130 may receive image data DATA and a data control signal DCS from the controller 150. The data driver 130 may operate in response to the data control signal DCS. According to some embodiments, the data control signal DCS may include a source start signal, a source shift clock, a source output enable signal, and the like.

The data driver 130 may receive voltages from the voltage generator 140. The data driver 130 may apply data signals having grayscale voltages corresponding to the image data DATA to the first to n-th data lines DL1 to DLn using the received voltages. When a gate signal is applied to each of the first to m-th gate lines GL1 to GLm, the data signals corresponding to the image data DATA may be applied to the data lines DL1 to DLn. Accordingly, the sub-pixels SP may generate light corresponding to the data signals, and the display panel DP may display an image.

According to some embodiments, the gate driver 120 and data driver 130 may include complementary metal-oxide semiconductor (CMOS) circuit elements.

The voltage generator 140 may operate in response to a voltage control signal VCS from the controller 150. The voltage generator 140 may be configured to generate a plurality of voltages and provide the generated voltages to components of the display device DD, such as the gate driver 120, the data driver 130, and the controller 150. The voltage generator 140 may generate the plurality of voltages by receiving an input voltage from the outside of the display device DD and regulating the received voltage.

The voltage generator 140 may generate a first power source voltage and a second power source voltage. The generated first and second power source voltages may be provided to the sub-pixels SP through power source lines PL. According to some embodiments, at least one of the first or second power source voltages may be provided from the outside of the display device DD.

Additionally, the voltage generator 140 may provide various voltages and/or signals. For example, the voltage generator 140 may provide one or more initialization voltages that are applied to the sub-pixels SP. For example, during a sensing operation for sensing electrical characteristics of transistors and/or light emitting elements of the sub-pixels SP, a reference voltage (e.g., a set or predetermined reference voltage) may be applied to the first to n-th data lines DL1 to DLn, and the voltage generator 140 may generate the reference voltage and transmit the reference voltage to the data driver 130. For example, during a display operation for displaying an image on the display panel DP, common pixel control signals may be applied to the sub-pixels SP, and the voltage generator 140 may generate the pixel control signals. According to some embodiments, the voltage generator 140 may provide the pixel control signals to the sub-pixels SP through pixel control lines PXCL. FIG. 1 shows a case where the pixel control lines PXCL are connected between the voltage generator 140 and the display panel DP, but embodiments are not limited thereto. For example, the pixel control lines PXCL may be connected between the gate driver 120 and the display panel DP. In this case, the pixel control signals may be transmitted from the voltage generator 140 to the pixel control lines PXCL through the gate driver 120.

The controller 150 may control all operations of the display device DD. The controller 150 may receive input image data IMG and a control signal CTRL corresponding thereto from the outside. The controller 150 may provide the gate control signal GCS, the data control signal DCS, and the voltage control signal VCS in response to the control signal CTRL.

The controller 150 may convert the input image data IMG to be suitable for the display device DD or the display panel DP to output the image data DATA. According to some embodiments, the controller 150 may align the input image data IMG to be suitable for the sub-pixels SP in a row unit to output the image data DATA.

Two or more components of the data driver 130, the voltage generator 140, and the controller 150 may be mounted on a single integrated circuit. As shown in FIG. 1, the data driver 130, the voltage generator 140, and the controller 150 may be included in a driver integrated circuit DIC. In this case, the data driver 130, the voltage generator 140, and the controller 150 may be functionally separate components within a single driver integrated circuit DIC. According to some embodiments, at least one of the data driver 130, the voltage generator 140, or the controller 150 may be provided as a separate component from the driver integrated circuit DIC.

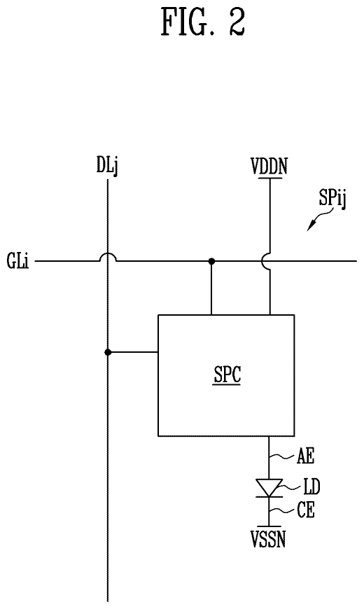

FIG. 2 is a block diagram illustrating aspects of one of sub-pixels of FIG. 1. FIG. 2 shows, as an example, a sub-pixel SPij arranged in an i-th row (i may be an integer greater than or equal to 1 and less than or equal to m) and a j-th column (j may be an integer greater than or equal to 1 and less than or equal to n) among the sub-pixels SP of FIG. 1.

Referring to FIG. 2, the sub-pixel SPij may include a sub-pixel circuit SPC and a light emitting element LD.

The light emitting element LD may be connected between a first power source voltage node VDDN and a second power source voltage node VSSN. In this case, the first power source voltage node VDDN may be a node that transmits the first power source voltage VDD of FIG. 1, and the second power source voltage node VSSN may be a node that transmits the second power source voltage VSS of FIG. 1.

An anode electrode AE of the light emitting element LD may be connected to the first power source voltage node VDDN through the sub-pixel circuit SPC, and a cathode electrode CE of the light emitting element LD may be connected to the second power source voltage node VSSN. For example, the anode electrode AE of the light emitting element LD may be connected to the first power source voltage node VDDN through one or more transistors included in the sub-pixel circuit SPC.

The sub-pixel circuit SPC may be connected to an i-th gate line GLi among the first to m-th gate lines GL1 to GLm of FIG. 1, an i-th emission control line ELi among first to m-th emission control lines EL1 to ELm of FIG. 1, and a j-th data line DLj among the first to n-th data lines DL1 to DLn of FIG. 1. The sub-pixel circuit SPC may be configured to control the light emitting element LD according to signals received through these signal lines.

The sub-pixel circuit SPC may operate in response to a gate signal received through the i-th gate line GLi. The i-th gate line GLi may include one or more sub-gate lines. According to some embodiments, as shown in FIG. 2, the i-th gate line GLi may include first and second sub-gate lines SGL1 and SGL2. The sub-pixel circuit SPC may operate in response to gate signals received through the first and second sub-gate lines SGL1 and SGL2. In this way, when the i-th gate line GLi includes two or more sub-gate lines, the sub-pixel circuit SPC may operate in response to gate signals received through corresponding sub-gate lines.

The sub-pixel circuit SPC may operate in response to an emission control signal received through the i-th emission control line ELi. According to some embodiments, the i-th emission control line ELi may include one or more sub-emission control lines. When the i-th emission control line ELi includes two or more sub-emission control lines, the sub-pixel circuit SPC may operate in response to emission control signals received through corresponding sub-emission control lines.

The sub-pixel circuit SPC may receive a data signal through the j-th data line DLj. The sub-pixel circuit SPC may store a voltage corresponding to the data signal in response to at least one of the gate signals received through the first and/or second sub-gate lines SGL1 and/or SGL2. In response to the emission control signal received through the i-th emission control line Eli, the sub-pixel circuit SPC may control a current flowing from the first power source voltage node VDDN to the second power source voltage node VSSN through the light emitting element LD according to the stored voltage. Accordingly, the light emitting element LD may generate light with a luminance corresponding to the data signal.

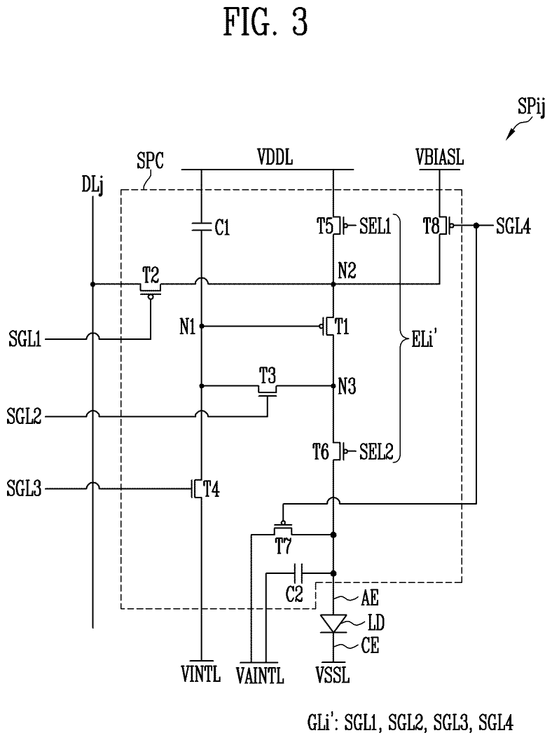

FIG. 3 is a circuit diagram illustrating aspects of a sub-pixel of FIG. 2.

Referring to FIG. 3, a sub-pixel SPij may include a sub-pixel circuit SPC and a light emitting element LD.

The sub-pixel circuit SPC may be connected to an i-th gate line GLi′, an i-th emission control line ELi′, and a j-th data line DLj. Compared with the i-th gate line GLi of FIG. 2, the i-th gate line GLi′ may further include a third sub-gate line SGL3 and a fourth sub-gate line SGL4. Compared with the i-th emission control line ELi of FIG. 2, the i-th emission control line ELi′ may include a first sub-emission control line SEL1 and a second sub-emission control line SEL2.

The sub-pixel circuit SPC may include first to eighth transistors T1 to T8, and first and second capacitors C1 and C2.

The first transistor T1 may be connected between a first power source voltage line VDDL and the anode electrode AE. A gate electrode of the first transistor T1 may be connected to a first node N1, and thus the first transistor T1 may be turned on according to a voltage level of the first node N1. The first transistor T1 may be referred to as a driving transistor.

The second transistor T2 may be connected between the j-th data line DLj and a second node N2. A gate electrode of the second transistor T2 may be connected to the first sub-gate line SGL1, and thus the second transistor T2 may be turned on in response to a gate signal of the first sub-gate line SGL1. The second transistor T2 may be referred to as a switching transistor.

The third transistor T3 may be connected between the first node N1 and a third node N3. A gate electrode of the third transistor T3 may be connected to the second sub-gate line SGL2, and thus the third transistor T3 may be turned on in response to a gate signal of the second sub-gate line SGL2.

The fourth transistor T4 may be connected between the first node N1 and a first initialization voltage line VINTL. The first initialization voltage line VINTL may be configured to transmit a first initialization voltage which is a negative voltage. According to some embodiments, the first initialization voltage may be provided by the voltage generator 140 of FIG. 1. In other embodiments, the first initialization voltage may be provided by a device external to the display device. A gate electrode of the fourth transistor T4 may be connected to the third sub-gate line SGL3, and thus the fourth transistor T4 may be turned on in response to a gate signal of the third sub-gate line SGL3.

The fifth transistor T5 may be connected between the second node N2 and the first power source voltage line VDDL. A gate electrode of the fifth transistor T5 may be connected to the first sub-emission control line SEL1, and thus the fifth transistor T5 may be turned on in response to an emission control signal of the first sub-emission control line SEL1.

The sixth transistor T6 may be connected between the third node N3 and the anode electrode AE. A gate electrode of the sixth transistor T6 may be connected to the second sub-emission control line SEL2, and thus the sixth transistor T6 may be turned on in response to an emission control signal of the second sub-emission control line SEL2.

The seventh transistor T7 may be connected between a second initialization voltage line VAINTL and the anode electrode AE. The second initialization voltage line VAINTL may be configured to transmit a second initialization voltage which is a negative voltage. According to some embodiments, the second initialization voltage may be provided by the voltage generator 140 of FIG. 1. In other embodiments, the second initialization voltage may be provided by a device external to the display device. A gate electrode of the seventh transistor T7 may be connected to the fourth sub-gate line SGL4, and thus the seventh transistor T7 may be turned on in response to a gate signal of the fourth sub-gate line SGL4.

The eighth transistor T8 may be connected between the second node N2 and a bias voltage line VBIASL. A gate electrode of the eighth transistor T8 may be connected to the fourth sub-gate line SGL4, and thus the eighth transistor T8 may be turned on in response to the gate signal of the fourth sub-gate line SGL4.

The first capacitor C1 may be electrically connected between the first node N1 and the first power source voltage line VDDL. The second capacitor C2 may be electrically connected between the anode electrode AE and the second initialization voltage line VAINTL.

As such, the sub-pixel circuit SPC may include the first to eighth transistors T1 to T8, and the first and second capacitors C1 and C2. However, embodiments are not limited thereto. The sub-pixel circuit SPC may be implemented as any one of various types of circuits including a plurality of transistors and one or more capacitors. For example, the sub-pixel circuit SPC may include two transistors and one capacitor. According to some embodiments of the sub-pixel circuit SPC, the number of sub-gate lines included in the i-th gate line GLi′ and the number of sub-emission control lines included in the i-th emission control line ELi′ may vary.

Among the first to eighth transistors T1 to T8, the first, second, fifth, sixth, seventh, and eighth transistors T1, T2, T5, T6, T7, and T8, excluding the third and fourth transistors T3 and T4, may be P-type transistors. The third and fourth transistors T3 and T4 may be N-type transistors. However, embodiments according to the present disclosure are not limited thereto. For example, all of the first to eighth transistors T1 to T8 may be P-type transistors.

According to some embodiments, the first to eighth transistors T1 to T8 may include an amorphous silicon semiconductor, a monocrystalline silicon semiconductor, a polycrystalline silicon semiconductor, an oxide semiconductor, or the like.

The light emitting element LD may include the anode electrode AE, the cathode electrode CE, and a light emitting layer. The light emitting layer may be located between the anode electrode AE and the cathode electrode CE. After a data signal transmitted through the j-th data line DLj is reflected in a voltage of the second node N2, the fifth and sixth transistors T5 and T6 may be turned on when emission control signals of the first and second sub-emission control lines SEL1 and SEL2 are enabled to a low level. In addition, the first transistor T1 may be turned on according to a voltage of the first node N1, and thus current may flow from the first power source voltage node VDDN to the second power source voltage node VSSN. The light emitting element LD may emit light according to the amount of current flowing.

According to some embodiments, by providing the second capacitor C2 connected to the anode electrode AE, a voltage of the anode electrode AE can be prevented from unintentionally fluctuating. For example, by providing the second capacitor C2 connected between the anode electrode AE and the second initialization voltage line VAINTL to which a negative voltage is applied, the voltage of the anode electrode AE can be prevented from unintentionally rapidly increasing. For example, when expressing black grayscale through the light emitting element LD, the voltage of the anode electrode AE may be maintained stably without increasing, so that the light emitting element LD can be prevented from unintentionally emitting light.

When expressing black grayscale, power consumption can be reduced by preventing or reducing unintentional emission of light by the light emitting element LD, and image quality characteristics can be relatively improved, thereby relatively improving the screen reliability of the display device.

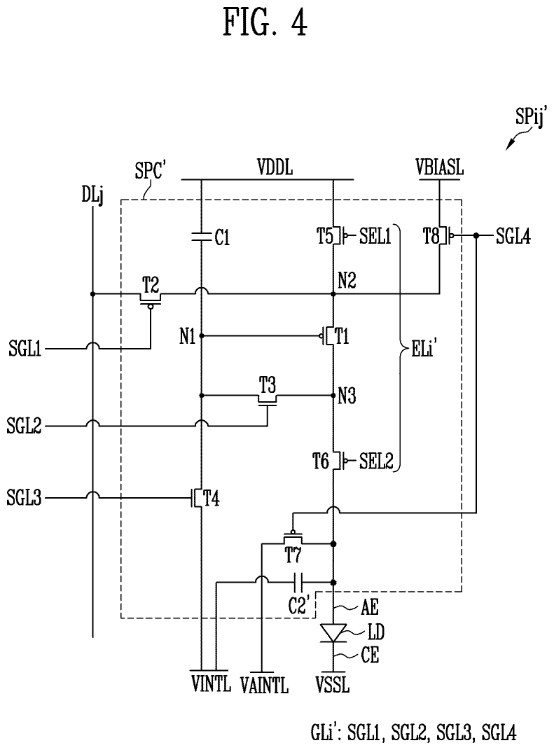

FIG. 4 is a circuit diagram illustrating aspects of the sub-pixel of FIG. 2.

Referring to FIG. 4, a sub-pixel SPij′ may include a sub-pixel circuit SPC′ and a light emitting element LD.

The sub-pixel circuit SPC′ may include first to eighth transistors T1 to T8 and first and second capacitors C1 and C2′. The sub-pixel circuit SPC′ may be configured similarly to the sub-pixel circuit SPC of FIG. 3, except for the second capacitor C2′. Hereinafter, some overlapping descriptions may be omitted.

The second capacitor C2′ may be connected between the anode electrode AE and the first initialization voltage line VINTL. According to some embodiments, by providing the second capacitor C2′ connected to the anode electrode AE, the voltage of the anode electrode AE can be prevented from unintentionally fluctuating. For example, by providing the second capacitor C2′ connected between the anode electrode AE and the first initialization voltage line VINTL to which a negative voltage is applied, the voltage of the anode electrode AE can be prevented from unintentionally rapidly increasing. For example, when expressing black grayscale through the light emitting element LD, the voltage of the anode electrode AE may be maintained stably without increasing, so that the light emitting element LD can be prevented from unintentionally emitting light.

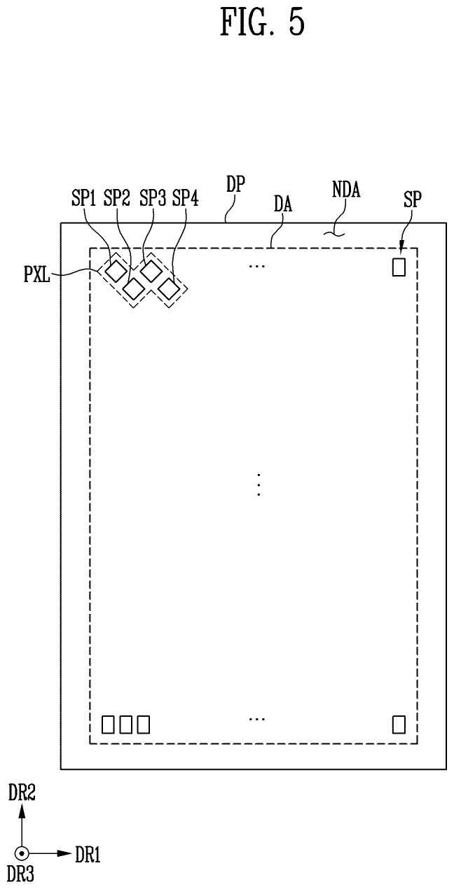

FIG. 5 is a plan view illustrating aspects of a display panel of FIG. 1.

Referring to FIG. 5, the display panel DP may include a display area DA and a non-display area NDA. The display panel DP may display an image through the display area DA. The non-display area NDA may be arranged around the display area DA.

The display panel DP may include the sub-pixels SP in the display area DA. The sub-pixels SP may be arranged along a first direction DR1 and a second direction DR2 intersecting the first direction DR1. For example, the sub-pixels SP may be arranged in a zigzag shape along the first direction DR1 and the second direction DR2. As another example, the sub-pixels SP may be arranged in a matrix form along the first direction DR1 and the second direction DR2. The arrangement of the sub-pixels SP may vary depending on embodiments. The first direction DR1 may be a row direction, and the second direction DR2 may be a column direction.

Two or more sub-pixels among a plurality of sub-pixels SP may constitute one pixel PXL. In FIG. 5, the pixel PXL is shown as including four sub-pixels SP1 to SP4, but embodiments are not limited thereto. For example, the pixel PXL may include two or three sub-pixels. Hereinafter, for convenience of description, it is assumed that the pixel PXL includes first to fourth sub-pixels SP1 to SP4.

The first to fourth sub-pixels SP1 to SP4 may be arranged in first to fourth sub-pixel areas, respectively. Each of the first to fourth sub-pixels SP1 to SP4 may generate light of one of various colors such as red, green, blue, cyan, magenta, and yellow. Hereinafter, for a clear and concise explanation, it is assumed that the first sub-pixel SP1 is configured to generate red light, the second sub-pixel P2 and the fourth sub-pixel SP4 are configured to generate green light, and the third sub-pixel SP3 is configured to generate blue light.

Each of the first to fourth sub-pixels SP1 to SP4 may include at least one light emitting element configured to generate light. According to some embodiments, light emitting elements of the first to fourth sub-pixels SP1 to SP4 may generate light of the same color. For example, the light emitting elements of the first to fourth sub-pixels SP1 to SP3 may generate blue light. According to some embodiments, the light emitting elements of the first to fourth sub-pixels SP1 to SP4 may generate light of different colors. For example, the light emitting elements of the first to fourth sub-pixels SP1 to SP4 may generate red, green, blue, and green light, respectively.

As the display panel DP, a display panel capable of self-emitting light such as a light emitting diode (LED) display panel using a micro-scale or nano-scale light emitting diode as a light emitting element, or an organic light emitting (OLED) display panel using an organic light emitting diode as a light emitting element may be used.

Components for controlling the sub-pixels SP and transmitting signals provide from pads may be located in the non-display area NDA. Signal lines connected to the first to m-th gate lines GL1 to GLm and the first to n-th data lines DL1 to DLn shown in FIG. 1 may be located in the non-display area NDA.

At least one of the gate driver 120, the data driver 130, the voltage generator 140, or the controller 150 shown in FIG. 1 may be located in the non-display area NDA of the display panel DP. According to some embodiments, the gate driver 120 may be located in the non-display area NDA. In this case, the data driver 130, the voltage generator 140, and the controller 150 may be implemented as the driver integrated circuit DIC of FIG. 1 separated from the display panel DP, and the driver integrated circuit DIC may be connected to wirings located in the non-display area NDA. According to some embodiments, the gate driver 120 may be implemented as a single integrated circuit separate from the display panel DP together with the data driver 130, the voltage generator 140, and the controller 150.

According to some embodiments, the display area DA may have various shapes. The display area DA may have a closed loop shape including straight and/or curved sides. For example, the display area DA may have a shape such as a polygon, a circle, a semicircle, or an ellipse.

According to some embodiments, the display panel DP may have a flat display surface. According to some embodiments, the display panel DP may have a display surface that is at least partially rounded. According to some embodiments, the display panel DP may be bent, folded, or rolled. In these cases, the display panel DP and/or a substrate of the display panel DP may include materials having flexible properties.

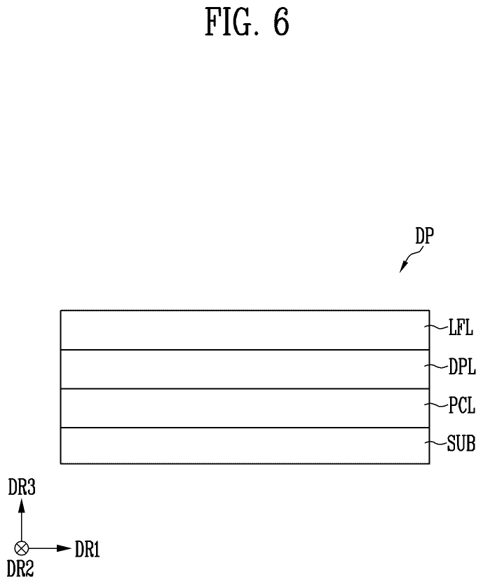

FIG. 6 is a cross-sectional view illustrating aspects of the display panel of FIG. 5.

Referring to FIG. 6, the display panel DP may include a substrate SUB, and a pixel circuit layer PCL, a display element layer DPL, and a light functional layer LFL sequentially laminated in a third direction DR3 intersecting the first and second directions DR1 and DR2 on the substrate SUB.

The substrate SUB may be made of an insulating material such as glass or resin. For example, the substrate SUB may include a glass substrate. As another example, the substrate SUB may include a PI (Polyimide) substrate. As another example, the substrate SUB may include a silicon wafer substrate formed using a semiconductor process.

According to some embodiments, the substrate SUB may be made of a flexible material that can be bent or folded, and may have a single-layer structure or a multi-layer structure. For example, the flexible material may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, or cellulose acetate propionate. However, embodiments are not limited thereto.

The pixel circuit layer PCL may be located on the substrate SUB. The pixel circuit layer PCL may include insulating layers, and semiconductor electrodes and conductive electrodes located between the insulating layers. The conductive electrodes of the pixel circuit layer PCL may function as circuit elements, wirings, or the like.

The circuit elements of the pixel circuit layer PCL may include the sub-pixel circuit SPC (see FIG. 2) of each of the sub-pixels SP of FIG. 3. In other words, the circuit elements of the pixel circuit layer PCL may be provided as transistors and one or more capacitors of the sub-pixel circuit SPC.

The wirings of the pixel circuit layer PCL may include wirings connected to the sub-pixels SP. The wirings of the pixel circuit layer PCL may include various signal lines and/or voltage lines necessary to drive the display element layer DPL.

The display element layer DPL may be located on the pixel circuit layer PCL. The display element layer DPL may include the light emitting elements of the sub-pixels SP.

The light functional layer LFL may be located on the display element layer DPL. The light functional layer LFL may include light conversion patterns having color conversion particles and/or scattering particles. For example, the color conversion particles may include quantum dots. The quantum dots may change the wavelength (or color) of light emitted from the display element layer DPL. The light functional layer LFL may further include light scattering patterns having scattering particles. According to some embodiments, the light conversion patterns and the light scattering patterns may be omitted.

The light functional layer LFL may further include a color filter layer including color filters. The color filter may selectively transmit light of a specific wavelength (or a specific color). According to some embodiments, the color filter layer may be omitted.

A window may be provided on the light functional layer LFL to protect an exposed surface (or upper surface) of the display panel DP. The window may protect the display panel DP from external impact. The window may be coupled to the light functional layer LFL through an optically transparent adhesive. The window may have a multilayer structure selected from a glass substrate, a plastic film, or a plastic substrate. This multilayer structure may be formed through a continuous process or an adhesive process using an adhesive layer. All or part of the window may be flexible.

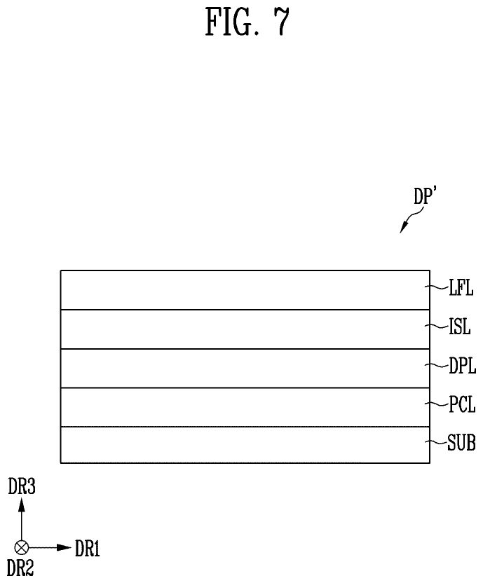

FIG. 7 is a cross-sectional view illustrating aspects of the display panel of FIG. 5.

Referring to FIG. 7, a display panel DP′ may include a substrate SUB, a pixel circuit layer PCL, a display element layer DPL, an input sensing layer ISL, and a light functional layer LFL. The substrate SUB, the pixel circuit layer PCL, the display element layer DPL, and the light functional layer LFL may be configured similarly to the substrate SUB, the pixel circuit layer PCL, the display element layer DPL, and the light functional layer LFL described with reference to FIG. 4. Hereinafter, some overlapping descriptions may be omitted.

The input sensing layer ISL may detect a user's input on the upper surface (or display surface) of the display panel DP′. The input sensing layer ISL may include components suitable for detecting an external object such as a user's hand, a pen, or the like. For example, the input sensing layer ISL may include touch electrodes.

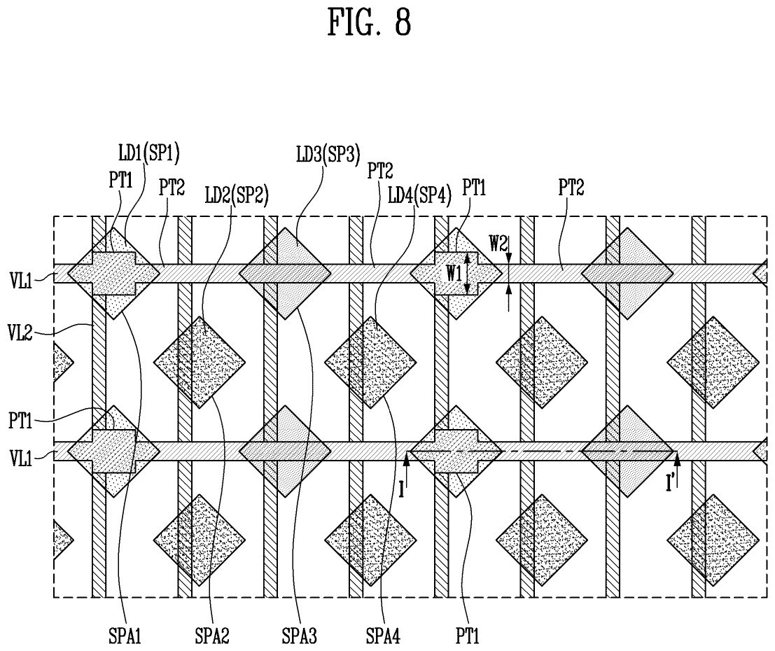

FIG. 8 is a plan view illustrating an enlarged portion of a display area in the display panel of FIG. 5. FIG. 8 shows only the substrate SUB, the pixel circuit layer PCL, and the anode electrode AE of display element layer DPL of FIG. 6.

Referring to FIG. 8 the first to fourth sub-pixels SP1 to SP4 (see FIG. 5) located in first to fourth sub-pixel areas SPA1 to SPA4 may include first to fourth light emitting elements LD1 to LD4. In this case, each of the first to fourth light emitting elements LD1 to LD4 may be provided as the light emitting element LD of FIGS. 2 to 4.

At least one of the first to fourth light emitting elements LD1 to LD4 may emit light of a different color from the other one. For example, the first light emitting element LD1 may emit red light, the second light emitting element LD2 and the fourth light emitting element LD4 may emit green light, and the third light emitting element LD3 may emit blue light. However, embodiments are not limited thereto. In this case, among the first to fourth light emitting elements LD1 to LD4, a threshold voltage of the first light emitting element LD1 emitting red light may be the lowest.

A first voltage line VL1 and a second voltage line VL2 may be located between the substrate SUB and the first to fourth light emitting elements LD1 to LD4. Each of the first voltage line VL1 and the second voltage line VL2 may be electrically connected to the first to fourth sub-pixels SP1 to SP4. Each of the first voltage line VL1 and the second voltage line VL2 may transmit a voltage to the first to fourth sub-pixels SP1 to SP4.

The first voltage line VL1 may overlap at least one of the first to fourth light emitting elements LD1 to LD4 and may be closer to the first to fourth light emitting elements LD1 to LD4 in the third direction DR3 than the second voltage line VL2. In FIG. 8, the first voltage line VL1 is shown as overlapping the first and third light emitting elements LD1 and LD3, but embodiments are not limited thereto.

The first voltage line VL1 may receive a negative voltage. That is, the first voltage line VL1 may be electrically connected to the first to fourth sub-pixels SP1 to SP4 and may provide the negative voltage to the first to fourth sub-pixels SP1 to SP4.

For example, the first voltage line VL1 may receive an anode initialization voltage (see FIG. 3). That is, the first voltage line VL1 may be provided as the second initialization voltage line VAINTL of FIG. 3. As another example, the first voltage line VL1 may receive a gate initialization voltage (see FIG. 4). That is, the first voltage line VL1 may be provided as the first initialization voltage line VINTL of FIG. 4. As another example, first voltage lines VL1 may include lines receiving the anode initialization voltage and lines receiving the gate initialization voltage.

The first voltage line VL1 may be electrically connected to the first to fourth sub-pixels SP1 to SP4 and may provide the negative voltage (for example, the anode initialization voltage or the gate initialization voltage) to the first to fourth sub-pixels SP1 to SP4.

The first voltage line VL1 may include at least one first portion PT1 and at least one second portion PT2 other than the first portion PT1. That is, the first voltage line VL1 may include a plurality of first portions PT1 and a plurality of second portions PT2.

The first portion PT1 may be defined as a portion having a larger width than the second portion PT2. Accordingly, a width W1 of the first portion PT1 may be greater than a width W2 of the second portion PT2. The first portion PT1 may overlap at least one of first to fourth anode electrodes. For example, the first portion PT1 may overlap a first anode electrode AE1. That is, a width W1 of a portion (first portion) overlapping the first anode electrode AE1 in the first voltage line VL1 may be larger than a width W2 of another portion (second portion) that does not overlap the first anode electrode AE1.

The second voltage line VL2 may receive a positive voltage. For example, the second voltage line VL2 may receive a data voltage. That is, the second voltage line VL2 may be provided as the data line DLj of FIG. 3 or FIG. 4. As another example, the second voltage line VL2 may receive a power source voltage (the first power source voltage or the second power source voltage). That is, the second voltage line VL2 may be provided as the first power source voltage line VDDL or the second power source voltage line VSSL of FIG. 3 or FIG. 4.

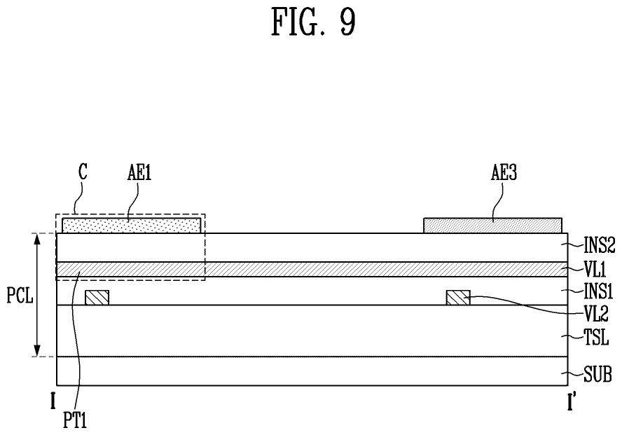

FIG. 9 is a cross-sectional view taken along the line I-I′ in FIG. 8.

FIG. 9 shows only the substrate SUB, the pixel circuit layer PCL, and the anode electrode of the display element layer DPL of FIG. 6.

Referring further to FIG. 9, the pixel circuit layer PCL may include a transistor layer TSL, a first voltage line VL1, a second voltage line VL2, a first insulating layer INS1, and a second insulating layer INS2. The anode electrode of the display element layer DPL may be located on the pixel circuit layer PCL and may be provided as the anode electrode AE of FIGS. 2 to 4.

The transistor layer TSL may be located on the substrate SUB. The transistor layer TSL may include one or more transistors, wirings connected to the transistors, and insulating layers located between the transistors and conductive electrodes constituting the wirings. The transistors included in the transistor layer TSL may be provided as the first to eighth transistors T1 to T8 of FIG. 3 or FIG. 4.

The second voltage line VL2 may be located on the transistor layer TSL. The first insulating layer INS1 may be located on the transistor layer TSL to cover the second voltage line VL2. The first voltage line VL1 may be located on the first insulating layer INS1. Each of the first voltage line VL1 and the second voltage line VL2 may include titanium and aluminum. However, embodiments are not limited thereto.

The second insulating layer INS2 may be located on the first insulating layer INS1 to cover the first voltage line VL1. The first to fourth anode electrodes may be located on the second insulating layer INS2. That is, the second insulating layer INS2 may be located between the first voltage line VL1 and the first to fourth anode electrodes.

An upper surface of the second insulating layer INS2 may be in contact with the first to fourth anode electrodes, and a lower surface of the second insulating layer INS2 may be in contact with the first voltage line VL1. In this case, because the first voltage line VL1 and the first and third anode electrodes AE1 and AE3 overlap each other and the second insulating layer INS2 is located therebetween, each of the first and third anode electrodes AE1 and AE3 and the first voltage line VL1 may form a capacitor.

Because the first anode electrode AE1 overlaps the first portion PT1 of the first voltage line VL1 and the third anode electrode AE3 overlaps the second portion PT2 of the first voltage line VL1, an area where the first anode electrode AE1 overlaps the first voltage line VL1 may be larger than an area where the third anode electrode AE3 overlaps the first voltage line VL1. Therefore, the capacitance of a capacitor C configured by the first anode electrode AE1 and the first voltage line VL1 may be greater than the capacitance of a capacitor configured by the third anode electrode AE3 and the first voltage line VL1.

For example, the capacitor C may be provided as the second capacitor C2 between the light emitting element LD and the second initialization voltage line VAINTL in FIG. 3. That is, the first anode electrode AE1 may be provided as one electrode of the capacitor C, and the first portion PT1 of the first voltage line VL1 provided as the second initialization voltage line VAINTL may be provided as the other electrode of the capacitor C. As another example, the capacitor C may be provided as the second capacitor C2 between the light emitting element LD and the first initialization voltage line VINTL in FIG. 4. That is, the first anode electrode AE1 may be provided as one electrode of the capacitor C, and the first portion PT1 of the first voltage line VL1 provided as the first initialization voltage line VINTL may be provided as the other electrode of the capacitor C.

According to some embodiments, by configuring the width of the first portion PT1 overlapping the first anode electrode AE1 in the first voltage line VL1 to be larger than that of the other portions, the capacitance of the capacitor C configured by the first anode electrode AE1 and the first voltage line VL1 can be increased. In addition, by configuring the capacitor C with the first voltage line VL1, the voltage of the first anode electrode AE1 constituting the capacitor C can be prevented from unintentionally fluctuating. For example, by connecting the capacitor C between the first anode electrode AE1 and the first voltage line VL1 to which a negative voltage is applied, the voltage of the first anode electrode AE1 can be prevented from unintentionally rapidly increasing. For example, when expressing black grayscale through the first light emitting element LD1, the voltage of the first anode electrode AE1 may be maintained stably without increasing, so that the first light emitting element LD1 can be prevented from unintentionally emitting light. As a result, power consumption can be reduced and image quality characteristics can be relatively improved, thereby relatively improving the screen reliability of the display device.

The threshold voltage of the first light emitting element LD1 may be lower than threshold voltages of the second to fourth light emitting elements LD2 to LD4. This may mean that when the voltage of the first anode electrode AE1 of the first light emitting element LD1 increases unintentionally, the possibility that the first light emitting element LD1 emits light is higher than the possibility that the second to fourth light emitting elements LD2 to LD4 emit light. According to some embodiments of the present disclosure, by providing the capacitor C connected to the first anode electrode AE1 of the first light emitting element LD1, the first light emitting element LD1 having a relatively high possibility of emitting light can be prevented from unintentionally emitting light.

In FIG. 8, the capacitor C connected to the first anode electrode AE1 of the first light emitting element LD1 may be provided, the capacitor connected to the third anode electrode AE3 of the third light emitting element LD3 and having a smaller capacitance than the capacitor C may be provided, and capacitors connected to the second and fourth light emitting elements LD2 and LD4 may not be provided.

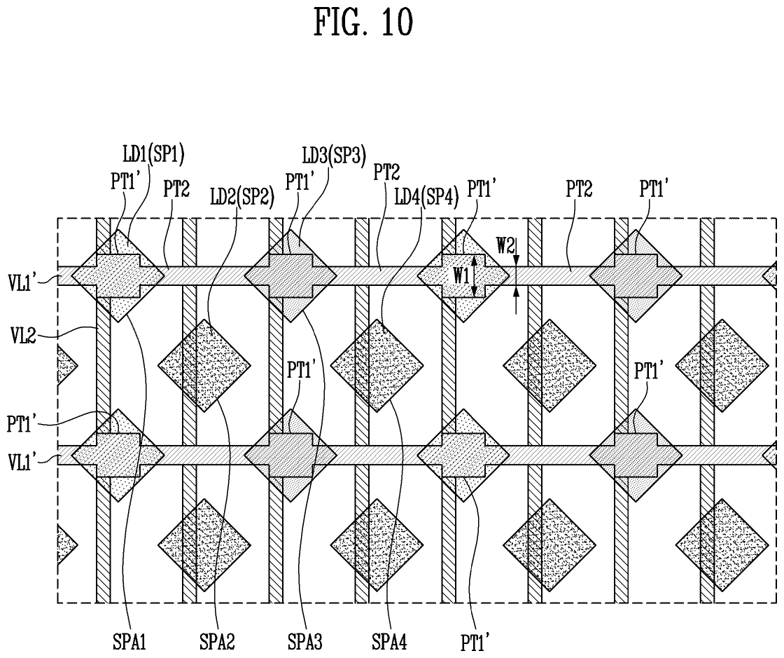

FIG. 10 is a plan view illustrating aspects of the display panel of FIG. 8.

The embodiments according to FIG. 10 may be the same (or substantially the same) as the embodiments according to FIG. 8 except for the shape of a first voltage line VL1′.

Referring to FIG. 10, the first voltage line VL1′ may include at least one first portion PT1′ and at least one second portion PT2. That is, the first voltage line VL1′ may include a plurality of first portions PT1′ and a plurality of second portions PT2.

A width W1 of the first portion PT1′ may be greater than a width W2 of the second portion PT2. The first portion PT1′ may overlap with two or more of the first to fourth anode electrodes. For example, the first portion PT1′ may overlap the first anode electrode AE1 and the third anode electrode AE3. That is, portions of the first voltage line VL1′ that overlap the anode electrodes (for example, the first anode electrode AE1 and the third anode electrode AE3) that overlap the first voltage line VL1′ among the first to fourth anode electrodes may have a larger width than other portions.

Because each of the first anode electrode AE1 and the third anode electrode AE3 overlaps the first portion PT1′ of the first voltage line VL1′, the capacitance of a capacitor configured by the first portion PT1′ and the first anode electrode AE1 and the capacitance of a capacitor configured by the first portion PT1′ and the third anode electrode AE3 can be increased. That is, by configuring the width of the first portion PT1′ overlapping each of the first and third anode electrodes AE1 and AE3 in the first voltage line VL1′ to be large, the capacitance of the capacitor configured by each of the first and third anode electrodes AE1 and AE3 and the first voltage line VL1′ can be increased.

In FIG. 10, the capacitor connected to the first anode electrode AE1 of the first light emitting element LD1 may be provided, the capacitor connected to the third anode electrode AE3 of the third light emitting element LD3 and having a similar capacitance to the capacitor may be provided, and capacitors connected to the second and fourth light emitting elements LD2 and LD4 may not be provided. However, embodiments are not limited thereto. In other embodiments, a capacitor connected to each of the anode electrodes of at least two of the first to fourth light emitting elements LD1 to LD4 may be provided. For example, when the first voltage line VL1′ overlaps all of the first to fourth anode electrodes AE1 to AE4, a capacitor connected to the first anode electrode AE1 of the first light emitting element LD1, a capacitor connected to the second anode electrode of the second light emitting element LD2, a capacitor connected to the third anode electrode AE3 of the third light emitting element LD3, and a capacitor connected to the fourth anode electrode of the fourth light emitting element LD4 may all be provided.

A display device according to some embodiments may be applicable to various types of electronic devices. According to some embodiments, an electronic device includes the above-described display device and may further include other modules or devices having additional functions in addition to the display device.

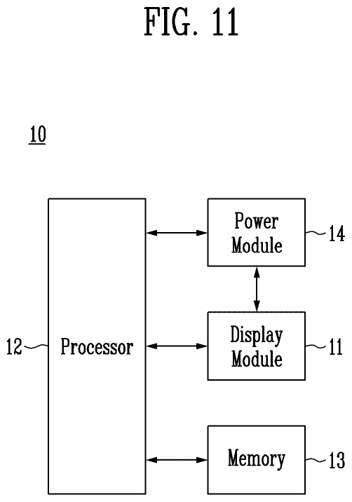

FIG. 11 is a block diagram of an electronic device according to some embodiments. Referring to FIG. 1, the electronic device 10 may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), or a controller.

The memory 13 may store data and/or information used to operate the processor 12 or the display module 11. When the processor 12 executes an application stored in the memory 13, image data signals and/or input control signals may be transferred to the display module 11. The display module 11 may process the provided signals and output image information on a display screen.

The power module 14 may include a power supply module, such as a power adapter or a battery device, and a power conversion module. The power conversion module converts power supplied by the power supply module and generates power to operate the electronic device 10.

At least one of the above-described components of the electronic device 10 may be included in the display device according to some embodiments as described above. In addition, in terms of functionality, some of the individual modules included in one module may be included in the display device and others may be provided separately from the display device. For example, the display module 11 is included in the display device, whereas the processor 12, the memory 13, and the power module 14 are not included in the display device and are instead provided separately in the electronic device 10.

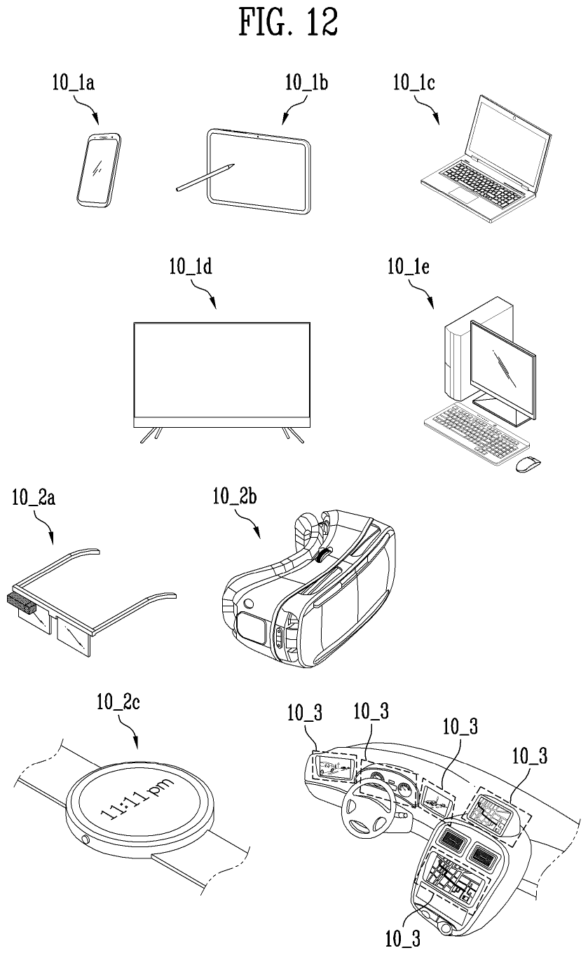

FIG. 12 shows schematic views of various embodiments of an electronic device.

Referring to FIG. 12, various types of electronic devices to which embodiments of a display device are applied may include an electronic device to display images such as a smartphone 10_1a, a tablet PC 10_1b, a laptop computer 10_1c, a television (TV) 10_1d, and a desktop monitor 10_1e, a wearable electronic device including a display module such as smart glasses 10_2a, a head-mounted display (HMD) 10_2b, and a smart watch 10_2c, and an automotive electronic device 10_3 including a display module such as a center information display (CID) located at the instrument cluster, the center fascia, and the dashboard of a vehicle, and a room mirror display.

According to the embodiments described above, by configuring the width of a portion overlapping an anode electrode in a voltage line that applies a negative voltage to be larger than other portions, thereby increasing the capacitance of a capacitor connected to the anode electrode, the voltage of the anode electrode can be prevented from unintentionally fluctuating. Accordingly, when expressing black grayscale through a light emitting element, the voltage of the anode electrode may be maintained stably without increasing, so that the light emitting element can be prevented from unintentionally emitting light.

When expressing black grayscale on a display device, power consumption can be reduced by preventing the light emitting element LD from unintentionally emitting light, and image quality characteristics can be relatively improved, thereby relatively improving the screen reliability of the display device.

Effects according to the embodiments are not limited by the above-described contents, and more various other effects are included in the present specification.

Although the technical spirit of embodiments according to the present disclosure has been specifically described according to the above-described embodiments, it should be noted that the above-described embodiments are intend to illustrate aspects of some embodiments of the present disclosure and not to limit the scope of embodiments according to the present disclosure. Those of ordinary skill in the art to which the present invention pertains will understand that various modifications are possible within the scope of the technical spirit of embodiments according to the present disclosure.

Therefore, the technical protection scope of embodiments according to the present disclosure is not limited to the detailed description described in the specification, but should be determined by the append claims, and their equivalents. In addition, all changes or modifications derived from the meaning and scope of the claims and their equivalents should be construed as being included in the scope of embodiments according to the present disclosure.

What is claimed is:

1. A display device comprising:
a substrate;
an anode electrode on the substrate; and
a first voltage line between the substrate and the anode electrode and configured to receive a negative voltage,
wherein in the first voltage line, a first portion overlapping the anode electrode has a width greater than a second portion not overlapping the anode electrode.

2. The display device of claim 1, further comprising:
an insulating layer between the anode electrode and the first voltage line,
wherein an upper surface of the insulating layer contacts the anode electrode, and a lower surface of the insulating layer contacts the first voltage line.

3. The display device of claim 2, wherein the anode electrode and the first voltage line constitute a capacitor.

4. The display device of claim 1, wherein the first voltage line is configured to receive an anode initialization voltage.

5. The display device of claim 1, wherein the first voltage line is configured to receive a gate initialization voltage.

6. The display device of claim 1, further comprising:
a first transistor connected between a first power source voltage line and the anode electrode and having a gate electrode connected to a first node;
a second transistor connected between the first node and a first initialization voltage line and having a gate electrode connected to a first gate line;
a third transistor connected between the anode electrode and a second initialization voltage line and having a gate electrode connected to a second gate line; and
a light emitting element connected between the anode electrode and a second power source voltage line.

7. The display device of claim 6, wherein the second initialization voltage line is the first voltage line.

8. The display device of claim 6, wherein the first initialization voltage line is the first voltage line.

9. The display device of claim 1, wherein the first voltage line includes titanium and aluminum.

10. The display device of claim 1, further comprising:
a second voltage line on the substrate and configured to receive a positive voltage.

11. The display device of claim 10, wherein the second voltage line is configured to receive a data voltage.

12. The display device of claim 10, wherein the second voltage line is configured to receive a power source voltage.

13. A display device comprising:
a substrate;
first to third light emitting elements on the substrate and respectively including first to third anode electrodes respectively in first to third sub-pixel areas; and
a first voltage line between the substrate and the first to third anode electrodes and configured to receive a negative voltage,
wherein in the first voltage line, at least one first portion has a width greater than a second portion other than the first portion, and
wherein the first portion overlaps at least one of the first to third anode electrodes.

14. The display device of claim 13, wherein the first to third light emitting elements are configured to emit light of different colors.

15. The display device of claim 14, wherein the first light emitting element is configured to emit red light,
wherein the second light emitting element is configured to emit green light, and
wherein the third light emitting element is configured to emit blue light.

16. The display device of claim 15, wherein the first portion overlaps one of the first to third anode electrodes.

17. The display device of claim 15, wherein the first portion overlaps each of two or more of the first to third anode electrodes.

18. An electronic device, comprising:
a processor configured to provide input image data; and
a display device configured to display an image based on the input image data,
wherein the display device comprises:
a substrate;
an anode electrode on the substrate; and
a first voltage line between the substrate and the anode electrode and configured to receive a negative voltage,
wherein in the first voltage line, a first portion overlapping the anode electrode has a width greater than a second portion not overlapping the anode electrode.
